(19) United States
(12) Patent Application Publication
(10) Pub. No.: US 2008/0186070 A1
(43) Pub. Date: Aug. 7, 2008

(54) HIGHER OPERATING FREQUENCY LATCH CIRCUIT

(76) Inventors: Arun Sundaresan Iyer, New Delhi (IN); Abhishek Kumar, Bangalore (IN); Zahir Parkar, Bangalore (IN)

Correspondence Address: TEXAS INSTRUMENTS INCORPORATED, P O BOX 655474, M/S 3999, DALLAS, TX, 75265, US

(21) Appl. No.: 11/380,427

(22) Filed: Apr. 27, 2006

(51) Int. Cl. H03K 3/289

(52) U.S. Cl. 327/203; 327/202

(57) ABSTRACT

A latch or flip flop circuit with an increased operating frequency is disclosed. In particular, the operating frequency of the latch is increased by reducing the set up time of the latch circuit. A regenerative circuit is provided between the transmission gate of the latch circuit and the data output. The regenerative circuit comprises a pull up circuit and a pull down circuit. The circuit arrangement of the present invention may be applied to flip flop or latch circuits in combination with other flip flop or latch circuits such as a Master-Slave configuration.

### TECHNICAL FIELD

The present invention relates to flip flop or latch circuits, and means for improving their operation.

### BACKGROUND

Digital logic circuitry forms the basis for many electronic circuits, providing products to the consumer ranging from computational devices to household and entertainment appliances.

A fundamental element of a digital circuit is the flip flop or latch circuit which can be used to process data in accordance with Boolean logic rules as will be understood by the person skilled in the art.

FIG. 1 shows a representation of one form of flip flop—the D flip flop 10. D flip flop 10 has a data input D 11 and a data output Q 12. D flip flop 10 also has a second input, or a clock input 13 for a clock signal to be applied to D flip flop 10.

Data that is applied to the input 11 appears at the output 12. One form of digital circuit design using flip flops is known as synchronous design. In such a design, the passage of data through the circuit is dependent upon a common clock signal applied to the devices in the circuit. In the case of the D flip flop 10, the data applied to input 11 will only appear on output 12 after the clock signal applied to clock input 13 changes from one state to another.

As technology advances, it is important to be able to design circuit topologies that are able to operate at great speeds. In circuits employing flip flops, the speed of operation is measured by the maximum rate at which the clock signal can change. This is known as the clock frequency.

In flip flop circuits, a number of factors limit the rate at which the clock signal can run. Consider FIG. 2, which shows two flip flops 10 and 20. The output 12 of flip flop 10 becomes the input 21 of flip flop 20. The two flip flops 10, 20 are synchronised by common clock signal 1 applied to clock inputs 13 and 23 respectively.

The maximum operating frequency F of this circuit arrangement is given by:

F⁻¹=T_{clk-Q1}+T_{comb}+T_{su,2}−T_{skew} (1)

Where:

T_{clk-Q1} is the Clk-Q Propagation Delay of the flip flop;

T_{comb} is the Propagation delay of the combinational block;

Tₛᵤ is the set up time of the flip flop; and

T_{skew} is the clock skew between the two interacting flip flops in the path.

The operating frequency F of the system is therefore dependent upon a number of different delays. If one or more of these delays could be reduced, this would result in a higher operating frequency of the system.

It is therefore an object of the present invention to provide a flip flop arrangement that has an improved operating frequency.

### SUMMARY OF THE INVENTION

According to a first aspect of the present invention, there is provided a latch circuit including a data input for inputting data to the latch circuit and having an input impedance, a data output for providing data from the latch circuit, a clock input for inputting a clock signal and a transmission gate for sampling the data input when the clock input is high, and a circuit element for reducing the input impedance to increase the operating frequency of the latch circuit.

In one embodiment, the circuit element acts to supply additional current to the latch circuit. In another embodiment, the circuit element is a regenerative circuit located between the transmission gate and the data output. In one aspect the regenerative circuit comprises a pull up circuit element and a pull down circuit element.

The pull up circuit element comprises a first transistor having an input for receiving an inverse data signal and a second transistor having an input for receiving an inverse clock signal. The pull down circuit element comprises a third transistor having an input for receiving the clock signal and a fourth transistor for receiving the inverse data signal. The transistors are Field Effect Transistors, each having a gate, a drain and a source terminal.

According to a second aspect of the present invention, there is provided a method for increasing the operating frequency of a latch circuit comprising a data input for inputting data to the latch circuit and having an input impedance, a data output for providing data from the latch circuit, a clock input for inputting a clock signal and a transmission gate for sampling the data input when the clock input is high, the method comprising reducing the input impedance.

According to a third aspect, there is provided a circuit arrangement including a latch circuit according to the first aspect of the present invention. In one embodiment, the circuit arrangement is a Master-Slave circuit arrangement.

According to a fourth aspect of the present invention, there is provided a regenerative circuit for use in a latch circuit, the regenerative circuit comprising a pull up circuit element and a pull down circuit element. The pull up circuit element comprises a first transistor having an input for receiving an inverse data signal and a second transistor having an input for receiving an inverse clock signal. The pull down circuit element comprises a third transistor having an input for receiving the clock signal and a fourth transistor for receiving the inverse data signal.

The transistors are Field Effect Transistors, each having a gate, a drain and a source terminal. The first transistor has its drain terminal connected to a latch circuit positive supply voltage and its source terminal connected to the drain terminal of the second transistor, and the second transistor has its drain terminal connected to the output of the transmission gate. The third transistor has its drain terminal connected to the output of the transmission gate and its source terminal connected to the drain terminal of the fourth transistor, and the fourth transistor has its source terminal connected to a latch circuit negative supply voltage.

### BRIEF DESCRIPTION OF THE DRAWINGS

The invention will now be described in detail with reference to the following drawings in which:

FIG. 1 shows a conventional flip flop element;

FIG. 2 shows an arrangement of two flip flop elements;

FIG. 3 shows an arrangement according to one aspect of the present invention; and

FIG. 4 shows a Master-Slave arrangement using the arrangement of FIG. 3.

### DETAILED DESCRIPTION

The present invention will now be described in detail with reference to one or more embodiments of the invention, examples of which are illustrated in the accompanying drawings. The examples and embodiments are provided by way of explanation only and are not to be taken as limiting to the scope of the invention. Furthermore, features illustrated or described as part of one embodiment may be used with one or more other embodiments to provide a further new combination.

It will be understood that the present invention will cover these variations and embodiments as well as variations and modifications that would be understood by the person skilled in the art.

Throughout the description, the term “flip flop” will be used interchangeably with the term “latch”.

According to one aspect of the present invention, the operating frequency of a flip flop circuit arrangement is increased by decreasing the set up time of the flip flop.

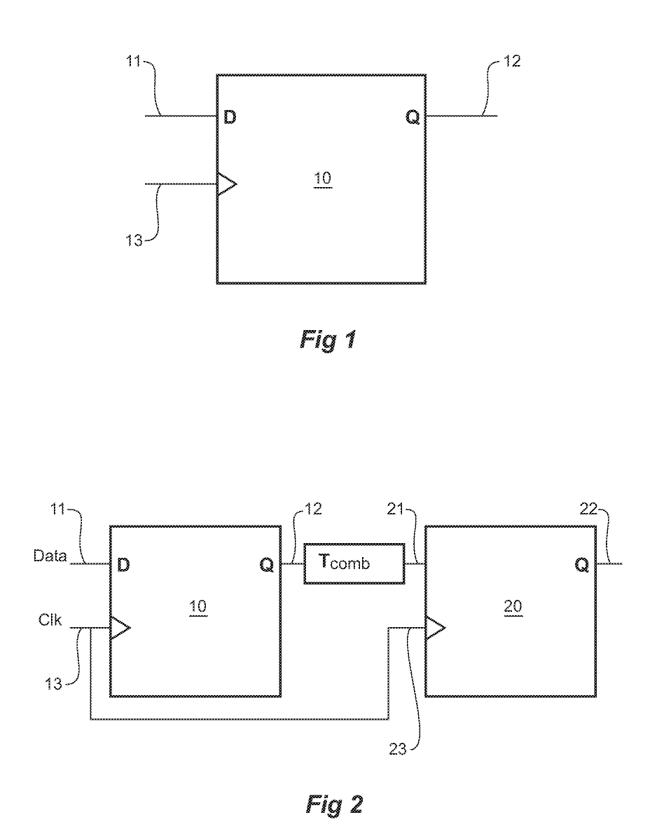

The set up time of a flip flop relates to the time required for data applied to the input 11 of a flip flop 10 (see FIG. 1) to become stable enough to be able to be successfully sampled by the clock signal. Thus the lower the set up time, the earlier the clock signal can be applied and therefore the system can be operated at a higher frequency.

The set up time of a flip flop is dependent upon the delay in data transmission from the input pin 11 to the node at which the clock signal samples the data. This delay is a function of the path delay (which is a constant for a given circuit) and the slew profile for a given signal. The slew profile is a measure of the time required for the data or signal to settle to or become stable at a given value.

According to another aspect of the present invention, the data is caused to settle very quickly by the application of a regenerative circuit located after the node at which the clock signal samples the data on input 11. The purpose of the regenerative circuit based latch/flip-flop implementation is to reduce the input impedance of the latch circuit 10 and hence speed up the output node of the latch circuit 10 by supplying extra current. This may be done by having circuit implementation that works in parallel with the Transmission Gate at the input of the latch or flip-flop.

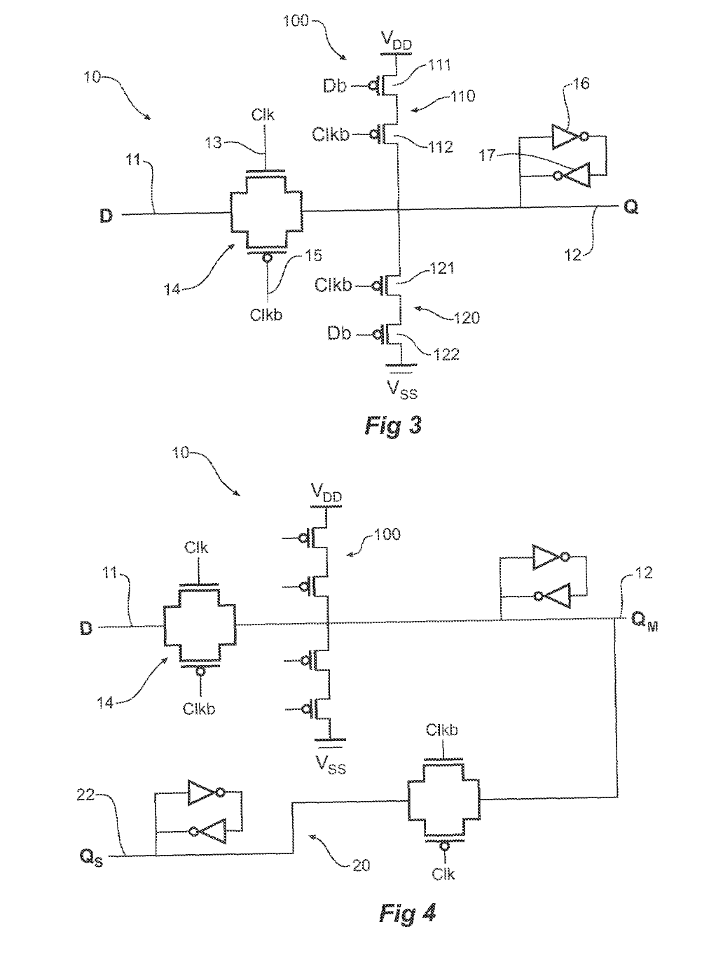

FIG. 3 shows a schematic of an arrangement according to this aspect of the present invention. There is shown latch circuit 10 with data input (D) 11, clock input 13 and data output (Q) 12. Also shown is transmission gate 14 comprising clock input 13 and inverted clock input 15. It is at transmission gate 14 that the data appearing at input 11 is sampled to be read into the latch circuit. Invertors 16 and 17 form part of the latch circuit as will be understood by the person skilled in the art.

According to this aspect of the present invention, a regenerative circuit 100 comprising regenerative pull up circuit element 110 and regenerative pull down circuit element 120 are provided after transmission gate 14 to supply additional current to the circuit of latch 10 to reduce the input impedance of the latch 10. This effectively results in decreasing the set up time of the latch 10, thus providing for an increased operating frequency.

Regenerative pull up circuit element 110 is made up of transistors 111 and 112, while regenerative pull down circuit 120 is made up of transistors 121 and 122. Each of these transistors is a Field Effect transistor (FET). In one form, these transistors may be provided by non-discrete elements. For example, transistors using 65 nm technology may be implemented, although it will be appreciated that any other suitable technology may be used. It will also be appreciated that the sizing of the transistors used in the regenerative logic will improve the drive of the latch/flip flop input (with improved robustness) but at the expense of power and parasitic loading. The sizing of these transistors must therefore be done in close synchronization with the transmission gate sizing and is dependent upon factors such as the required performance and power constraints. Of course it will be understood that any other type of switching element could be used, including bipolar transistors.

In one form, transistor 111 is a pMOS and has its source connected to a latch circuit positive supply voltage and its drain terminal connected to the source terminal of pMOS transistor 112, which in turn has its drain terminal connected to the output of the transmission gate 14. Transistor 121 is an nMOS and has its drain terminal connected to the output of the transmission gate 14 and its source terminal connected to the drain terminal of transistor 122, which in turn has its source terminal connected to a latch circuit negative or ground supply voltage. Transistor 122 is also an nMOS transistor.

The input Clkb to the gate of transistor 112 is the inverse of the clock signal Clk, while the input Db of transistor 111 is the inverse of data input D at input 11. The input Clk of transistor 121 is the same as the input to the Clk input 13 while the input Db to transistor 122 is also the inverse of the data input D at input 11. It will also be seen that the inputs to the transistors 111 and 112 of the regenerative pull up circuit element 110 are also negated.

The operation of the arrangement as shown in FIG. 3 is as follows. When the input data at input 11 (D)=1 or 0 and the Clock level at clock input 13 is low, the output (Q) 12 is the logic level retained in the latch's 10 memory element from the last operation.

When the input data at input 11 (D)=1 or 0 and the Clock level at clock input 13 is high, the transmission gate 14 begins to conduct and the logic level of D is passed to the output Q. In parallel, transistors 112 and 121 in the regenerative pull-up 110 and pull-down 120 circuits respectively start conducting and depending on the value of the Db signal, either the pull-up 110 or pull-down 120 branch begins to supply current to charge or discharge respectively the output Q 12. When the slew on the input D 11 is bad, the output Q 12 begins to charge/discharge slowly through the transmission gate 14, but after a small delay either the pull-up 110 or the pull-down 120 regenerative branches start conducting to supply sufficient current to speed up the operation on output Q 12.

It will understood that the terms “good” slews and “bad” slews are used because the absolute values of the slew changes with different technology nodes, implementation styles and design constraints. For example, what is “good” for 150 nm technology may not be “good” for 65 nm technology. The skilled person in the art will understand what these terms imply in the particular context of the application of the invention. In the particular application described herein (65 nm technology), slews that are substantially <100 pico-sec (ps) [rail-rail, or VDD-VSS/VSS-VDD full swing] are referred to as good slews; slews that are substantially >200 ps are referred to as bad slews. In the case of a 0.8 um technology, slews substantially <2 nano-sec (ns) are considered to be good slews and slews that are substantially >5 ns are considered to be bad slews.

This circuit implementation improves the Setup times and latency. Furthermore, because the regenerative circuit 100 provides an immediate static path to either Supply voltage or Ground, through the Pull-up 110 or Pull-down 120 elements, this proposed implementation is quite robust to noise.

Even though the proposed circuit speeds up the operation at bad data slews, it does not significantly degrade operation at good slews. This is because at good slews, most of the conduction happens through the transmission gate 14 to speed up operation of output Q 12.

FIG. 4 shows the application of the circuit of FIG. 3 in a Master-Slave flip flop arrangement (as shown in FIG. 2), where the input D 11 is the input to the arrangement, output QM 12 is the output of the Master latch circuit 10 and output Qs 22 is the output of the slave latch circuit 20.

The application of the present invention to a Master-Slave flip flop arrangement provides the benefits of reduced set up times and thus increased operating frequency to this and more complicated arrangements.

The regenerative circuit described herein may also be used in more than one latch of a circuit arrangement utilising multiple latches. For example, each latch of a Master-Slave flip flop arrangement may have its own regenerative circuit.

Another possible application of the present invention is to improve the hold time of the flip flops as well as to improve the Clk-Q delay of the flip flop, since that is actually the latency of the high latch and which can be improved as described earlier.

This is ideal for circuits like synchronizers, which are used for reliable interaction between two asynchronous domains (i.e. two circuit arrangements that are controlled by Clock signals that are not related).

1. A latch circuit comprising a data input for inputting data to the latch circuit and having an input impedance, a data output for providing data from the latch circuit, a clock input for inputting a clock signal and a transmission gate for sampling the data input when the clock input is high, and a circuit element for reducing the input impedance to increase the operating frequency of the latch circuit.

2. A latch circuit as claimed in claim 1 wherein the circuit element acts to supply additional current to the latch circuit.

3. A latch circuit as claimed in claim 2 wherein the circuit element is a regenerative circuit located between the transmission gate and the data output.

4. A latch circuit as claimed in claim 3 wherein the regenerative circuit comprises a pull up circuit element and a pull down circuit element.

5. A latch circuit as claimed in claim 4 wherein the pull up circuit element comprises a first transistor having an input for receiving an inverse data signal and a second transistor having an input for receiving an inverse clock signal.

6. A latch circuit as claimed in claim 4 wherein the pull down circuit element comprises a third transistor having an input for receiving the clock signal and a fourth transistor for receiving the inverse data signal.

7. A latch circuit as claimed in claim 5 or 6 wherein the transistors are Field Effect Transistors, each having a gate, a drain and a source terminal.

8. A latch circuit as claimed in claim 7 wherein the first transistor has its drain terminal connected to a latch circuit positive supply voltage and its source terminal connected to the drain terminal of the second transistor, and the second transistor has its drain terminal connected to the output of the transmission gate.

9. A latch circuit as claimed in claim 8 wherein the third transistor has its drain terminal connected to the output of the transmission gate and its source terminal connected to the drain terminal of the fourth transistor, and the fourth transistor has its source terminal connected to a latch circuit negative supply voltage.

10. A method for increasing the operating frequency of a latch circuit comprising a data input for inputting data to the latch circuit and having an input impedance, a data output for providing data from the latch circuit, a clock input for inputting a clock signal and a transmission gate for sampling the data input when the clock input is high, the method comprising reducing the input impedance.

11. A method as claimed in claim 10 wherein the input impedance is reduced by supplying additional current to the latch circuit.

12. A latch circuit as claimed in claim 11 wherein the additional current is supplied by way of a regenerative circuit located between the transmission gate and the data output.

13. A circuit arrangement including a latch circuit as claimed in claim 1.

14. A circuit arrangement as claimed in claim 13 wherein the circuit arrangement is a Master-Slave circuit arrangement.

15. A regenerative circuit for use in a latch circuit, the regenerative circuit comprising pull up circuit element and a pull down circuit element.

16. A regenerative circuit as claimed in claim 15 wherein the pull up circuit element comprises a first transistor having an input for receiving an inverse data signal and a second transistor having an input for receiving an inverse clock signal.

17. A regenerative circuit as claimed in claim 16 wherein the pull down circuit element comprises a third transistor having an input for receiving the clock signal and a fourth transistor for receiving the inverse data signal.

18. A regenerative circuit as claimed in claim 16 or 17 wherein the transistors are Field Effect Transistors, each having a gate, a drain and a source terminal.

19. A regenerative circuit as claimed in claim 18 wherein the first transistor has its drain terminal connected to a latch circuit positive supply voltage and its source terminal connected to the drain terminal of the second transistor, and the second transistor has its drain terminal connected to the output of the transmission gate.

20. A regenerative circuit as claimed in claim 19 wherein the third transistor has its drain terminal connected to the output of the transmission gate and its source terminal connected to the drain terminal of the fourth transistor, and the fourth transistor has its source terminal connected to a latch circuit negative supply voltage.
